(19) United States
(12) Patent Application Publication
(10) Pub. No.: US 2026/0190687 A1
(43) Pub. Date: Jul. 2, 2026

(54) DISPLAY APPARATUS

(71) Applicant: LG Display Co., Ltd., Seoul (KR)

(72) Inventors: Dongkyu LEE, Goyang-si (KR); Jungho BANG, Paju-si (KR); Kyu-Hwang LEE, Paju-si (KR); Munchan KANG, Goyang-si (KR)

(73) Assignee: LG Display Co., Ltd., Seoul (KR)

(21) Appl. No.: 19/205,075

(22) Filed: May 12, 2025

(30) Foreign Application Priority Data
Dec. 30, 2024 (KR) 10-2024-0200577

(51) Int. Cl. H10K 59/131; H10K 59/127

(52) U.S. Cl. CPC H10K 59/131; H10K 59/1275

(57) ABSTRACT

A display apparatus includes a first substrate having a plurality of first pads, each first pad including first patterns arranged with spacing gaps therebetween. A second substrate is on the first substrate and includes a plurality of second pads, each second pad including a second pattern coupled with the first patterns. The second patterns are inserted into the respective spacing gaps to contact the side surfaces of the first patterns, establishing electrical connection between the substrates through direct surface contact. An insulating material layer may be disposed between the substrates.

### CROSS-REFERENCE TO RELATED APPLICATION

This application claims priority from Korean Patent Application No. 10-2024-0200577 filed on December 30, 2024, in the Korean Intellectual Property Office, and all the benefits accruing therefrom under 35 U.S.C. 119, the contents of which in its entirety are herein incorporated by reference.

### BACKGROUND

### Technical Field

This specification relates to a display apparatus.

### DESCRIPTION OF THE RELATED ART

The display device is applied to various electronic devices such as televisions (TVs), smartphones, laptops, and tablets. To this end, research is ongoing to develop thinner, lighter, and lower-power display devices.

Examples of display devices include liquid crystal display (LCD), field emission display (FED), and organic light-emitting display (OLED) apparatuses.

The display device may include a display panel where a plurality of pixels are arranged and various electronic components for driving the display panel.

### BRIEF SUMMARY

Among various electronic components, a driver circuit chip (Drive-IC) can transmit power or signals provided through a printed circuit board to a display panel to control a plurality of pixels.

The method of bonding a driver circuit chip to a display panel may involve different technologies depending on the type of substrate on which the driver circuit chip is mounted. For example, methods of coupling the driver circuit chip to the display panel may include a chip-on-glass (COG) method, a chip-on-film (COF) method, or a chip-on-plastic (COP) method.

To electrically connect the driver circuit chip and the display panel, a conductive film with multiple conductive balls (or particles) dispersed in an insulating material may be used. For example, a film with numerous dispersed conductive balls can be placed between the display panel and the driver circuit chip and bonded via thermal compression. This allows the conductive balls to contact both the display panel and the driver circuit chip, enabling electrical connection between them.

However, when using a conductive film, defects in electrical connection may occur if the conductive balls are unevenly distributed within the insulating material. Particularly, as various electronic devices have recently become smaller and thinner, the size of electronic components within these devices has also decreased. Additionally, as the size of electrodes or bonding pads within electronic components shrinks, the pitch, or spacing between adjacent electrodes or bonding pads, has also reduced.

When conductive balls are not uniformly distributed between bonding pads with fine pitch and are clustered in local areas, a short circuit may occur between adjacent bonding pads. Alternatively, if the conductive balls are not distributed between the display panel and the driver circuit chip, open defects may occur, resulting in no electrical connection. Consequently, failures may arise where power or signals are not reliably delivered to the sub-pixels on the display panel.

Accordingly, the inventors of this specification, through various experiments, have provided various embodiments of a display apparatus capable of stably implementing electrical connection between the display panel and the driver circuit chip.

Specifically, the disclosed display apparatus achieves electrical connection between a driver circuit chip and a display panel through direct surface contact between complementary pad structures, eliminating the need for conductive balls. The pads are designed with interlocking branching patterns, where the second pads are inserted into gaps between first pads, ensuring stable mechanical and electrical coupling. The first pads have inclined surfaces while the second pads feature sharp edges, improving surface contact, reducing contact resistance, and enhancing signal transmission reliability.

This structure allows for finer pitch arrangements, reducing the size of pad areas and enabling more compact, high-resolution display devices. By omitting conductive balls, the design reduces or minimizes defects such as shorts and opens, lowers production energy requirements, and reduces greenhouse gas emissions.

For example, various embodiments of this specification provide a display apparatus capable of preventing electrical connection defects between the display panel and the driver circuit chip.

Various embodiments of this specification provide a display apparatus capable of preventing connection defects in bonding pads with a fine pitch.

Various embodiments of this specification provide a display apparatus capable of reducing the size of the pad portion disposed in the pad area adopting bonding pads with a finer pitch.

Various embodiments of this specification provide a display apparatus capable of reducing production energy and greenhouse gas emissions by preventing connection defects in bonding pads with fine pitch.

The technical benefits of the embodiments in this specification are not limited to the foregoing, and other benefits and advantages of the present disclosure not mentioned can be understood through the following description and will be more clearly understood through the embodiments of this specification. Moreover, it will be readily apparent that the benefits and advantages of this specification can be realized by the means and combinations thereof set forth in the claims.

A display apparatus according to an embodiment of this specification may include a first substrate on which a plurality of first pads each including first patterns arranged with spacing gaps in between are disposed, and a second substrate disposed on the first substrate, with a plurality of second pads each including a second pattern coupled with the first patterns, wherein the second patterns are inserted into the respective spacing gaps to contact the side surfaces of the first patterns.

### BRIEF DESCRIPTION OF THE SEVERAL VIEWS OF THE DRAWINGS

FIG. 1 is a plan view of a display apparatus according to the embodiments of this specification;

FIG. 2 is a diagram illustrating the components shown in FIG. 1 in an exploded view;

FIG. 3 is an enlarged plan view of area I of FIG. 2;

FIG. 4 is an enlarged plan view of area II of FIG. 2;

FIG. 5 is a cross-sectional view taken along line III-III′ of FIG. 1;

FIG. 6 is an enlarged view of area IV of FIG. 1;

FIG. 7 is a cross-sectional view taken along line V-V′ of FIG. 6 according to an embodiment of this specification;

FIG. 8 is a perspective view enlarging portion A of FIG. 7;

FIG. 9 is a cross-sectional view enlarging a portion where one first pad and one second pad are coupled;

FIG. 10 is a diagram illustrating a cross-section along line V-V′ of FIG. 6 according to another embodiment of this specification;

FIG. 11 is a diagram illustrating a display apparatus coupled using conductive balls;

FIGS. 12 to 15 are diagrams illustrating a display apparatus according to another embodiment of this specification;

FIGS. 16 to 18 are diagrams illustrating a display apparatus according to yet another embodiment of this specification; and

FIGS. 19 and 20 are diagrams illustrating a display apparatus according to still another embodiment of this specification.

### DETAILED DESCRIPTION

Advantages and features disclosed in this specification and methods of accomplishing the same may be understood more readily by reference to the detailed description of embodiments that will be made hereinafter with reference to the accompanying drawings. This specification is not limited to the embodiments described herein but may be embodied in various forms, and the embodiments are provided to ensure a complete disclosure of the disclosure and to fully convey the scope of the disclosure to those skilled in the art in the relevant technical field.

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

Throughout the specification, the same reference numerals refer to the same components. In addition, detailed descriptions of well-known technologies may be omitted in the specification to avoid obscuring the subject matter of the specification. When terms such as “comprises,” “has,” “includes,” or “is made up of” are used in this specification, it should be understood that unless “only” is specifically used, additional elements or steps can be included. Unless otherwise explicitly stated, when a component is expressed in the singular form, it is intended to encompass the plural form as well.

In interpreting the components, it is construed to include a margin of error even in the absence of explicit description.

When describing positional relationships, expressions such as “on,” “above,” “below,” or “beside” may indicate the positional relationship between two parts, and unless “immediately” or “directly” is used, one or more other parts may be located between the two parts.

When describing temporal relationships, expressions such as “after,” “following,” “next,” or “before” may indicate a sequence of events, and unless “immediately” or “directly” is used, non-continuous cases may also be included.

Terms like “first,” “second,” etc., are used to describe various components, but these components are not limited by these terms. These terms are merely used for distinguishing one component from the other components. Therefore, the first component mentioned hereinafter may be the second component in the technical sense of this specification.

As used herein, the term "connected" is intended to have the broadest possible meaning. Specifically, the phrase "A is connected to B" encompasses both a direct connection—where no intervening components or elements are present—and an indirect connection, where one or more intermediate components or elements exist between A and B. In other words, "A is connected to B" includes both direct physical or electrical coupling and indirect coupling through one or more intervening components. Unless explicitly stated otherwise, these terms do not require direct physical or electrical contact. The term "coupled" and "in contact" should be interpreted in the same manner.

The various features of the embodiments of the disclosure can combined or assembled together, either partially or entirely, in a technically diverse manner, and each embodiment can be independently implemented or in conjunction with related embodiments.

Hereinafter, a display apparatus according to each embodiment of this specification will be described with reference to the accompanying drawings.

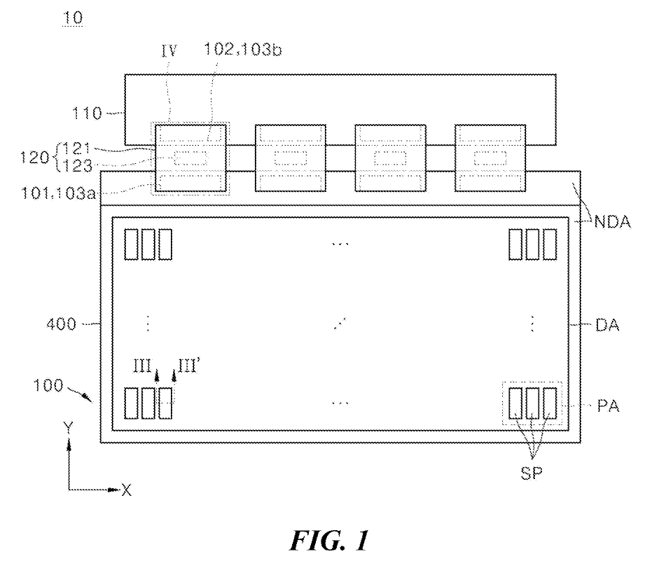

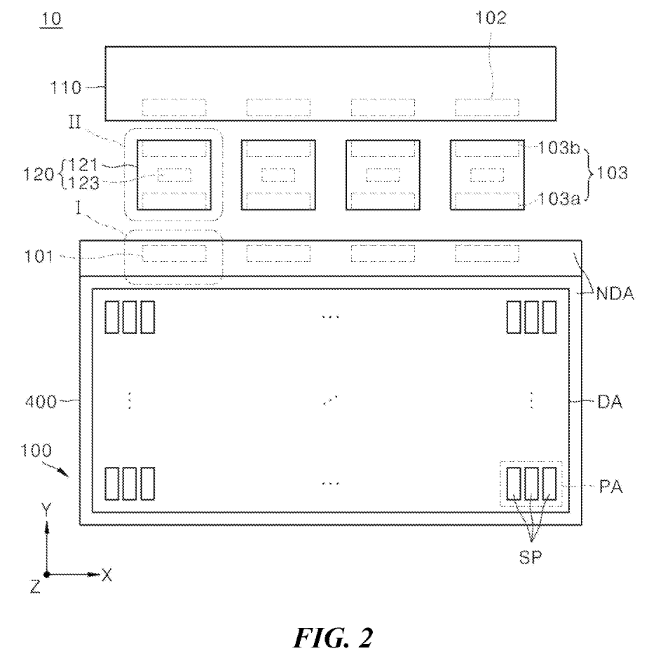

FIG. 1 is a plan view of a display apparatus according to embodiments of this specification. FIG. 2 is a diagram illustrating the components shown in FIG. 1 in an exploded view;

Referring to FIGS. 1 and 2, a display apparatus 10 according to the embodiments of this specification may include a display panel 100, a printed circuit board 110, and a driver circuit chip package 120. The display panel 100, the printed circuit board 110, and the driver circuit chip package 120 may be electrically connected to each other. The display apparatus 10 according to an embodiment of this specification may be configured using a chip-on-film (COF) method to couple the display panel 100 and the driver circuit chip package 120, but is not limited thereto.

The display panel 100 may include a first substrate 400.

The display panel 100 may include a display area DA and a non-display area NDA located outside the display area DA. The display panel 100 may include a plurality of light-emitting elements, circuit elements for driving the light-emitting elements, and a plurality of wirings (not shown).

The display area DA may be an area where an image is displayed, and the non-display area NDA may be an area where an image is not displayed. The non-display area NDA may be located in a peripheral area or a border area of the display panel 100, but is not limited thereto. For example, the area other than the emissive area where light is emitted externally on the display area DA may be referred to as the non-display area NDA.

A plurality of pixel areas PA may be disposed in the display area DA. Each pixel area PA may include a plurality of sub-pixels SP. An image may be displayed in the display area DA by applying driving signals to the plurality of sub-pixels SP. The non-display area NDA may include various wiring and circuits for driving the plurality of sub-pixels SP in the display area DA. For example, the non-display area NDA may include driving circuits such as a gate driving circuit and a data driving circuit. The non-display area NDA may include various drivers for driving the display area DA. For example, the drivers may include a gate driver and a data driver, but are not limited thereto.

The display panel 100 may include a plurality of first pad areas 101. The plurality of first pad areas 101 may be disposed on the non-display area NDA of the display panel 100. For example, the plurality of first pad areas 101 may be arranged spaced apart from each other along one edge of the display panel 100.

A printed circuit board 110 may be disposed corresponding to at least one edge of the non-display area NDA. The printed circuit board 110 may transmit various signals or supply power to the display panel 100 through the driver circuit chip package 120. The printed circuit board 110 may include a flexible substrate made of a flexible material. A third pad area 102, where a plurality of output pads are disposed, may be arranged along one edge of the printed circuit board 110.

The driver circuit chip package 120 may be disposed between the display panel 100 and the printed circuit board 110. A plurality of driver circuit chip packages 120 may be arranged.

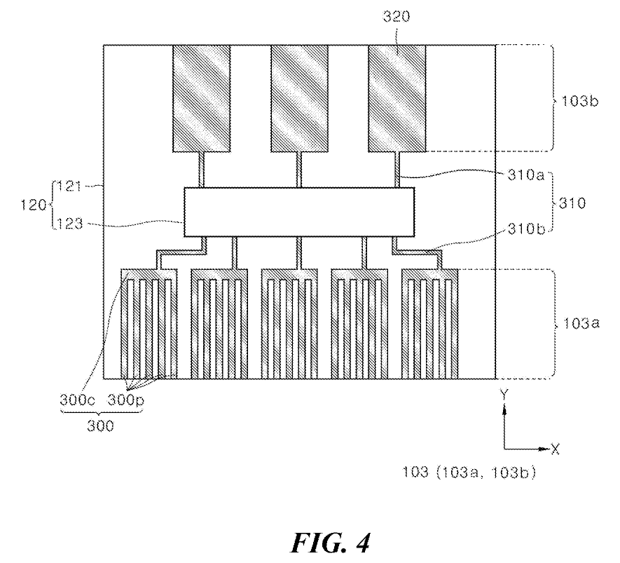

The driver circuit chip package 120 may include a second substrate 121, a driver circuit chip 123, a plurality of second pad areas 103 where a plurality of pads are disposed, and a plurality of wirings (not shown). The second substrate 121 may be a plastic film with flexibility. The driver circuit chip package 120 may include at least one driver circuit chip 123. The plurality of pads disposed in the second pad area 103 may include, for example, a plurality of output pads and a plurality of input pads. This will be described in detail with reference to FIG. 4.

The driver circuit chip package 120 may provide power or signals supplied from the printed circuit board 110 to the light-emitting elements of the display panel 100 and the circuit elements for driving the light-emitting elements. For example, the power or signals may include a high-potential voltage, a low-potential voltage, a scan signal, or a data signal.

One side of the driver circuit chip package 120 may be coupled to the display panel 100, and the other side may be coupled to the printed circuit board 110. For example, a first region 103a of the second pad area 103, disposed along one edge of the driver circuit chip package 120, may be arranged to overlap the first pad area 101 on the display panel 100. A second region 103b of the second pad area 103, disposed along the other edge of the driver circuit chip package 120, may be arranged to overlap the third pad area 102 on the printed circuit board 110.

In one example, the display panel 100 may include a bending area where a portion of the non-display area NDA is bent. When the bending area of the display panel 100 is bent, the printed circuit board 110 and the driver circuit chip package 120 may be disposed on the rear side of the display area DA of the display panel 100. The bending area may be a region located between the display panel 100 and the driver circuit chip package 120. For example, the bending area may be a portion of the non-display area NDA of the display panel 100 that does not overlap the driver circuit chip package 120.

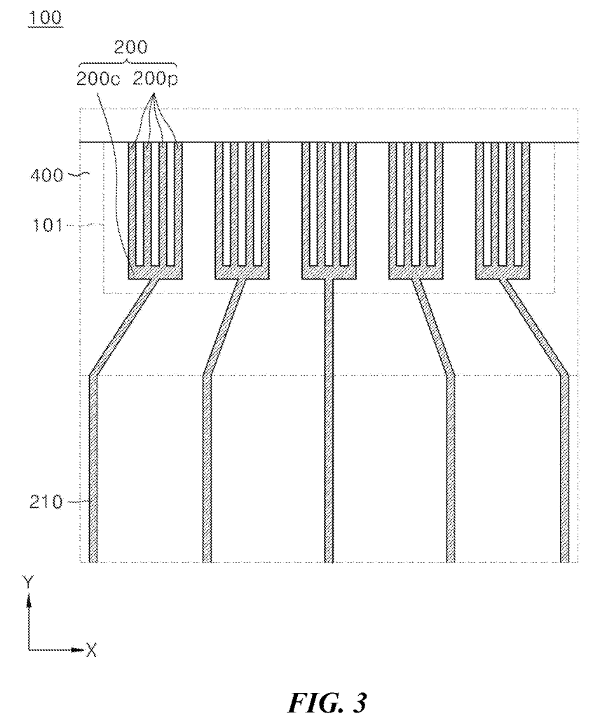

FIG. 3 is an enlarged plan view of area I of FIG. 2. FIG. 4 is an enlarged plan view of area II of FIG. 2. FIG. 3 illustrates one first pad area 101 on the display panel 100. FIG. 4 is an enlarged view of the driver circuit chip package 120.

Referring to FIG. 3, the display panel 100 may include a plurality of first pads 200 and a plurality of first wirings 210 disposed on one surface of the first substrate 400. Each of the plurality of first wirings 210 may be connected to a respective one of the first pads 200. The first pads 200 may be input pads. For example, the first pads 200 may be input pads where signals provided from the driver circuit chip package 120 are received. In one example, the surface of the first substrate 400 where the plurality of first pads 200 are disposed may be a connection surface coupled to the driver circuit chip package.

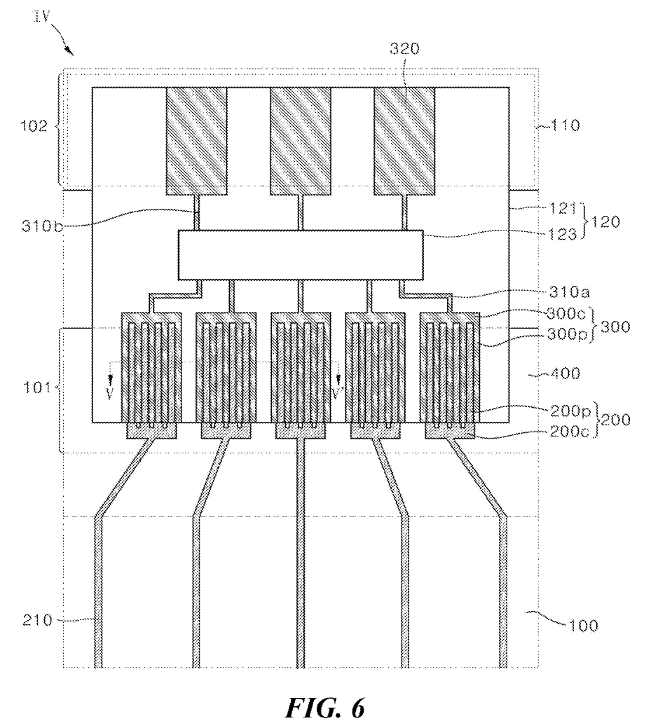

The plurality of first pads 200 may be disposed in the first pad area 101 located along one edge of the first substrate 400. The first pads 200 may be arranged spaced apart from each other along the first direction X of the first substrate 400. The first pads 200 may be connected to a second pad, which is an output pad of the driver circuit chip. This will be described in detail with reference to FIG. 6.

The first pads 200 may each include first patterns 200c and 200p arranged with spacing gaps therebetween. The first patterns 200c and 200p disposed on one first pad 200 may include a first-first pattern 200c and a plurality of first-second patterns 200p branching and extending from the first-first pattern 200c. The first-first pattern 200c and the plurality of first-second patterns 200p may be formed as an integral structure. The first-first pattern 200c may extend along the first direction X of the first substrate 400. The first-first pattern 200c may have a line or bar shape. One first-first pattern 200c may be connected to one of the plurality of wirings 210.

Each of the plurality of first-second patterns 200p may branch from the first-first pattern 200c and be arranged to extend in a second direction Y intersecting the first direction X. The adjacent plurality of first-second patterns 200p may be spaced apart from each other with a gap therebetween. For example, each of the plurality of first-second patterns 200p may be arranged spaced apart from each other along the first direction X of the first substrate 400 with a gap therebetween. The adjacent plurality of first-second patterns 200p may each have a length relatively longer than that of the first-first pattern 200c.

For example, a first signal supplied from the printed circuit board 100 may be provided to each of the plurality of first-second patterns 200p of the first pad 200 on the display panel 100. The first-second patterns 200p and the first-first pattern 200c may be formed as an integral structure to ensure that the same signal as the first signals supplied to each of the plurality of first-second patterns 200p is transmitted to the sub-pixels. Accordingly, the first signal supplied from the printed circuit board 100 may branch to each of the plurality of first-second patterns 200p and be merged into a single first signal at the first-first pattern 200c, then transmitted to a sub-pixel through one of the plurality of first wirings 210 connected to the first-first pattern 200c. In this case, the signal branched from the plurality of first-second patterns 200p and the signal at the first-first pattern 200c may be the same signal.

The signal branched from the plurality of first-second patterns 200p may be provided from the printed circuit board 110 and transmitted to the display panel 100 through the pads 300 and 320 of the driver circuit chip package 120 shown in FIG. 4.

Referring to FIG. 4, the driver circuit chip package 120 may include pads 300 and 320 and a plurality of second wirings 310 disposed on one surface of the second substrate 121. The pads 300 and 320 of the driver circuit chip package 120 may include second pads 300 and third pads 320. For example, the second pads 300 may be output pads that transmit signals to the display panel 100, and the third pads 320 may be input pads where signals or power supplied from the printed circuit board 110 are received. In one example, the surface of the second substrate 121 of the driver circuit chip package 120 where the pads 300 and 320 are disposed may be a connection surface coupled to the display panel 100 and the printed circuit board 110.

The second pads 300 may be disposed in the first region 103a of the second pad area 103 located along one edge of the second substrate 121. The second pads 300 may be arranged along the first direction X of the second substrate 121. The second pads 300 may be connected to the first pads 200 of the display panel 100.

The second pads 300 may each include second patterns 300c and 300p arranged with spacing gaps therebetween. The second patterns 300c and 300p disposed on one second pad 300 may include a second-first pattern 300c and a plurality of second-second patterns 300p branching and extending from the second-first pattern 300c. For example, the second-first pattern 300c may extend along the first direction X of the second substrate 121. The second-first pattern 300c may be connected to one of the plurality of second wirings 310. Each of the plurality of second-second patterns 300p may branch from the second-first pattern 300c and be arranged to extend in a second direction Y intersecting the first direction X.

The adjacent plurality of second-second patterns 300p may be spaced apart from each other with a gap therebetween. For example, each of the plurality of second-second patterns 300p may be arranged spaced apart from each other along the first direction X of the second substrate 121 with a gap therebetween. The second-first pattern 300c and the plurality of second-second patterns 300p may be formed as an integral structure. The second-first pattern 300c and each second-second pattern 300p may have a line or bar shape. Each second-second pattern 300p may have a length relatively longer than that of the second-first pattern 300c.

The third pads 320 may be disposed in the second region 103b of the second pad area 103 located along the other edge of the second substrate 121. The third pads 320 may be arranged spaced apart from each other along the first direction X of the second substrate 121. The third pads 320 may be connected to the printed circuit board 110. The third pads 320 may have a shape different from that of the second pads 300. In one embodiment, each of the third pads 320 may be configured as a polygonal plate. For example, one third pad 320 may have a rectangular shape with a vertical width in the second direction Y greater than the horizontal width in the first direction X.

A first portion 310a of the plurality of second wirings 310 may electrically connect the third pads 320 to the driver circuit chip 123. A second portion 310b of the plurality of second wirings 310 may electrically connect the second pads 300 to the driver circuit chip 123.

For example, a signal supplied from the printed circuit board 110 may be transmitted to the driver circuit chip 123 through the third pads 320 and the first portion 310a of the second wirings 310. The driver circuit chip 123 may convert the supplied signal and provide the converted signal to the display panel 100 through the second portion 310b of the second wirings 310 and the second pads 300.

The first signal supplied to the second-first pattern 300c of the second pads 300 in the driver circuit chip package 120 may branch to each of the plurality of second-second patterns 300p and be supplied toward the display panel 100. In this case, the signal supplied to the second-first pattern 300c and the signals branched to each of the plurality of second-second patterns 300p may be the same signal.

In one example, the signal supplied toward the display panel 100 through the second pads 300 may be transmitted to a thin-film transistor on the display panel 100, and the operation of each sub-pixel may be controlled through the thin-film transistor.

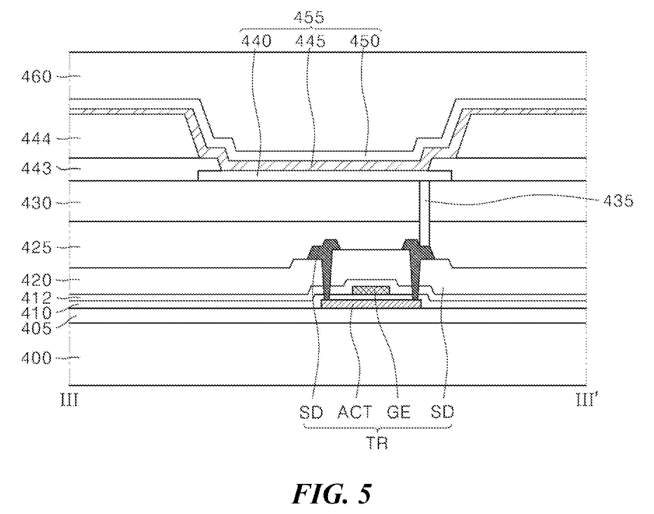

FIG. 5 is a cross-sectional view taken along line III-III′ of FIG. 1. FIG. 5 schematically illustrates a single sub-pixel.

Referring to FIGS. 1 and 5, the display panel 100 may include a plurality of light-emitting elements and circuit elements for driving the light-emitting elements disposed on the first substrate 400. A plurality of thin-film transistors TR, a plurality of light-emitting elements 455, and an encapsulation layer 460 may be disposed on the first substrate 400. Additionally, for convenience of explanation, FIG. 5 shows only one thin-film transistor TR and one light-emitting element 455. A cover substrate may further be included on the encapsulation layer 460.

In one embodiment, one sub-pixel may include a light-emitting element 455 and a pixel driving circuit for driving the light-emitting element 455. The pixel driving circuit may include a driving thin-film transistor, one or more switching thin-film transistors, and a capacitor.

The first substrate 400 may include a transparent insulating material with flexible properties. For example, the first substrate 400 may include glass or a plastic film. The first substrate 400 may be implemented, for example, as a multilayer structure with organic and inorganic insulating materials arranged alternately.

A buffer layer 405 may be disposed on the first substrate 400. The buffer layer 405 may block moisture or oxygen that may penetrate from the rear side of the first substrate 400. The buffer layer 405 may be a single layer or multilayer made of an inorganic insulating material such as silicon oxide (SiOx) or silicon nitride (SiNx).

A thin-film transistor TR may be disposed on the first substrate 400. The thin-film transistor TR may include a semiconductor layer ACT, a first insulating layer 405, a gate electrode GE, and source/drain electrodes SD. The first insulating layer 405 may be disposed between the semiconductor layer ACT and the gate electrode GE. For convenience of explanation, an embodiment of this specification describes a single thin-film transistor as an example, but is not limited thereto. For example, the display apparatus may include a plurality of thin-film transistors to drive the plurality of light-emitting elements 455.

The semiconductor layer ACT may be disposed on the buffer layer 405. The semiconductor layer ACT may be made of an oxide semiconductor or a silicon-based semiconductor material, but the embodiments of this specification are not limited thereto. For example, the semiconductor layer ACT may include a transparent oxide semiconductor material such as indium-gallium-zinc-oxide IGZO or indium-zinc-oxide IZO. Additionally, the semiconductor layer ACT may include a polysilicon semiconductor material or a low-temperature polysilicon semiconductor material. The semiconductor layer ACT may include a channel region, a source region, and a drain region.

The first insulating layer 410 may be disposed between the gate electrode GE and the semiconductor layer ACT. The semiconductor layer ACT may be covered by the first insulating layer 410. The first insulating layer 410 may be composed of a single layer or multiple layers of an inorganic insulating material including silicon oxide (SiOx) or silicon nitride (SiNx). The first insulating layer 410 may be referred to as a gate insulating layer. A light-shielding layer may be further included between the buffer layer 405 and the semiconductor layer ACT, or between the first substrate 400 and the buffer layer 405. The light-shielding layer may overlap the semiconductor layer ACT in the vertical direction to block external light incident on the semiconductor layer ACT. The light-shielding layer may include an opaque material.

A gate electrode GE may be disposed on the first insulating layer 410. The gate electrode GE may overlap the semiconductor layer ACT. For example, the gate electrode GE may be disposed overlapping the semiconductor layer ACT in the vertical direction. The region of the semiconductor layer ACT overlapping the gate electrode GE may be a channel region. Source/drain regions may be located on both sides of the channel region.

The gate electrode GE may be formed as a single layer or multiple layers made of any one of molybdenum (Mo), aluminum (Al), chromium (Cr), gold (Au), titanium (Ti), nickel (Ni), neodymium (Nd), copper (Cu), or an alloy thereof. However, the material is not limited thereto.

A second insulating layer 415 may be disposed on the gate electrode GE. The second insulating layer 415 may be a multilayer structure with a plurality of insulating layers stacked in the vertical direction. The second insulating layer 415 may be composed of a single layer or multiple layers of an inorganic insulating material including silicon oxide (SiOx) or silicon nitride (SiNx).

Source/drain electrodes SD, each connected to the source/drain regions of the semiconductor layer ACT, may be disposed penetrating the second insulating layer 415. The source/drain electrodes SD may extend to cover a portion of the upper surface of the second insulating layer 415.

Planarization layers 425 and 430 may be disposed on the second insulating layer 415 and the source/drain electrodes SD. The planarization layers 425 and 430 may planarize a step caused by underlying circuit elements such as the thin-film transistor TR to provide a flat surface. The planarization layers 425 and 430 may include a first planarization layer 425 and a second planarization layer 430. The first planarization layer 425 may cover the source/drain electrodes SD. The second planarization layer 430 may be disposed on the first planarization layer 425.

A contact electrode 435 penetrating the first planarization layer 425 and the second planarization layer 430 may be disposed. The contact electrode 435 may connect to the source/drain electrodes SD for electrical connection. The first and second planarization layers 425 and 430 may be composed of a single layer or multiple layers of an organic insulating material including acryl resin, epoxy resin, phenolic resin, polyamide resin, or polyimide resin. However, it is not limited thereto and may include an organic insulating material capable of planarizing a step.

A light-emitting element 455 may be disposed on the second planarization layer 430. The light-emitting element 455 may include a first electrode 440, a light-emitting layer 445, and a second electrode 450. The light-emitting layer 445 may be disposed between the first electrode 440 and the second electrode 450. The first electrode 440 may also be referred to as an anode electrode or pixel electrode, and the second electrode 450 may also be referred to as a cathode electrode or counter electrode, but the embodiments of this specification are not limited thereto.

The first electrode 440 may be disposed on the second planarization layer 430. One surface of the first electrode 440 may contact the upper surface of the contact electrode 435. Accordingly, the first electrode 440 may be electrically connected to the semiconductor layer ACT through the contact electrode 435 and the source/drain electrodes SD. For example, the first electrode 440 may be electrically connected to the source/drain region of the semiconductor layer ACT.

The first electrode 440 may be composed of a single layer or multiple layers of a transparent metal oxide including indium-tin-oxide (ITO) or indium-zinc-oxide (IZO), but the embodiments of this specification are not limited thereto. For example, the first electrode 440 may include a single layer or multilayer structure comprising a reflective metal layer formed of one of silver (Ag), aluminum (Al), gold (Au), nickel (Ni), chromium (Cr), or an alloy thereof.

A bank 443 may be disposed on the first electrode 440. The bank 443 may be arranged to cover the edge of the first electrode 430 while extending onto the second planarization layer 430. The bank 443 may separate adjacent sub-pixels. The bank 443 may include a bank hole exposing the central region of the first electrode 430. For example, the area exposed by the bank hole may be a light-emitting area.

The bank 443 may prevent light of different colors from adjacent sub-pixels from mixing and being output. The bank 443 may be composed of a single layer or multiple layers of an organic insulating film including polyimide, epoxy, or the like, but is not limited thereto. For example, the bank 443 may include an organic insulating material containing a black pigment or black dye. When the bank 443 includes a black pigment or black dye, it may block light from the outside or reflected light, thereby further improving the luminance of the display apparatus.

A spacer 444 may be disposed on the bank 443. The spacer 444 may include an organic insulating material. The spacer 444 may be formed of the same material as the bank 443, but is not limited thereto. The spacer 444 may prevent the light-emitting layer 445 disposed on the light-emitting area from directly receiving external impact, thereby protecting the light-emitting layer 445.

A light-emitting layer 445 may be disposed on the first electrode 440. The light-emitting layer 445 may be formed across the entire surface of the display area DA (see FIG. 1) to cover the exposed surfaces of the first electrode 440, the bank 443, and the spacer 444. In one embodiment, the light-emitting layer 445 may include an organic material that emits different colors in each sub-pixel, but is not limited thereto. In another embodiment, the light-emitting layer 445 may include an organic material that emits white light, with a color filter producing one of red, green, or blue colors.

The light-emitting layer 445 may include a stack structure comprising a hole transporting layer (HTL), an emission material layer (EML), an electron transporting layer (ETL), a hole blocking layer (HBL), a hole injecting layer (HIL), an electron blocking layer (EBL), and an electron injecting layer (EIL). When including a stack structure, it may comprise one or more stack structures. For example, a charge generation layer may be further included between the one or more stack structures. The charge generation layer may include a P-type charge generation layer and an N-type charge generation layer. The emission material layer (EML) within the stack structure of the light-emitting layer 445 may emit light through the recombination of holes injected from the first electrode 430 and electrons injected from the second electrode 450.

A second electrode 450 may be disposed on the light-emitting layer 445. The second electrode 450 may be formed to cover the light-emitting layer 445. The second electrode 450 may be commonly formed over a plurality of sub-pixels SP (see FIG. 1). For example, the second electrode 450 may be formed across the entire area of the display area DA (see FIG. 1). The second electrode 450 may be composed of a single layer or multiple layers including a reflective metal layer formed of one of silver (Ag), aluminum (Al), gold (Au), nickel (Ni), chromium (Cr), or an alloy thereof, but is not limited thereto. In one example, the second electrode 450 may include a transparent metal oxide such as indium-tin-oxide (ITO) or indium-zinc-oxide (IZO).

A light-emitting element 455 may be constituted by including the first electrode 430, the light-emitting layer 445, and the second electrode 450. An encapsulation layer 460 may be disposed on the light-emitting element 455. The encapsulation layer 460 may protect the light-emitting element 455 from external oxygen or moisture. The encapsulation layer 460 may include a multilayer structure with at least one inorganic insulating layer or organic insulating layer alternately stacked. The encapsulation layer 460 may prevent moisture from penetrating onto the light-emitting element 455.

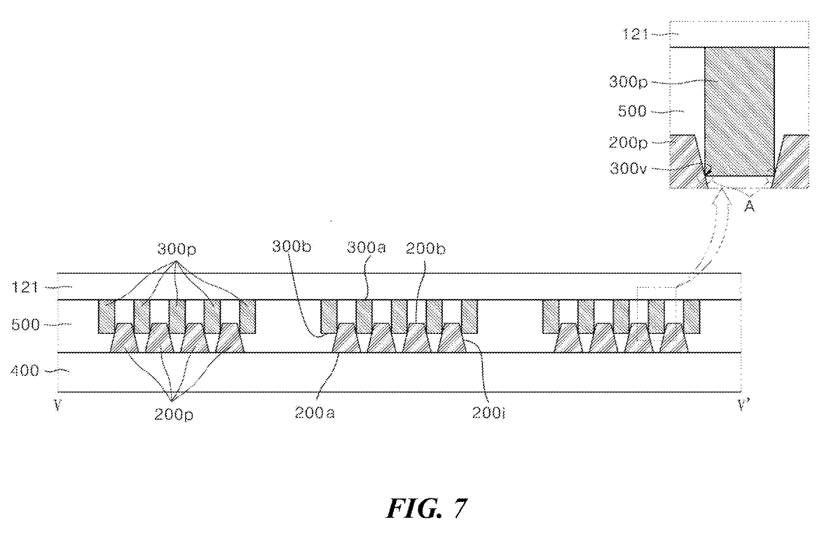

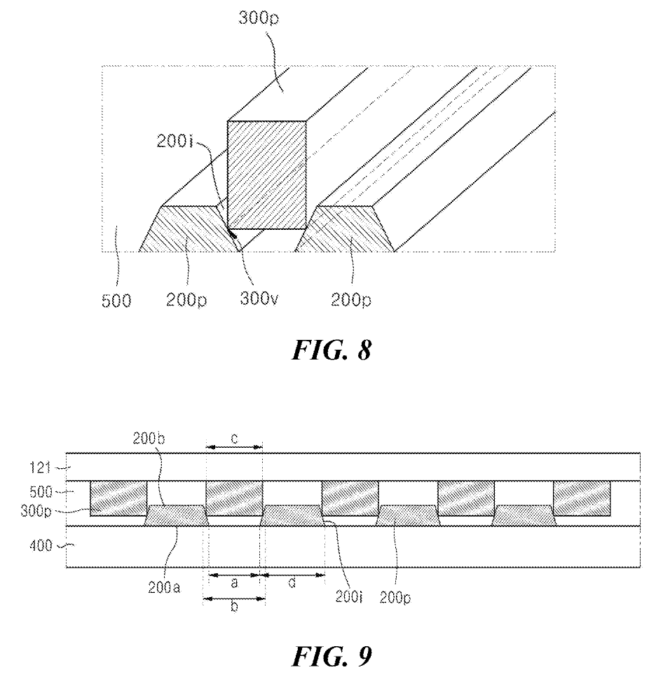

FIG. 6 is an enlarged view of area IV of FIG. 1. FIG. 7 is a cross-sectional view taken along line V-V′ of FIG. 6 according to an embodiment of this specification. FIG. 8 is a perspective view enlarging portion A of FIG. 7. FIG. 9 is a cross-sectional view enlarging a portion where one first pad and one second pad are coupled. For example, FIG. 6 is a diagram illustrating an enlarged view of the portion where the display panel and the driver circuit chip package are coupled.

Referring to FIGS. 6 to 8, the second pads 300 of the driver circuit chip package 120 may be electrically connected to the first pads 200 of the display panel 100.

The first pads 200 of the display panel 100 and the second pads 300 of the driver circuit chip package 120 may be aligned to overlap in the vertical direction. For example, the first-second patterns 200p of the first pad 200 of the display panel 100 may be positioned in the spacing gaps between the second-second patterns 300p of the second pad 300 of the driver circuit chip package 120. Additionally, the second-second patterns 300p of the second pad 300 of the driver circuit chip package 120 may be positioned in the spacing gaps between the first-second patterns 200p of the first pad 200 of the display panel 100. For example, the odd-numbered first-second pattern 200p of the first pad 200 of the display panel 100 may be positioned in the space between the odd-numbered second-second pattern 300p and the even-numbered second-second pattern 300p of the second pad 300 of the driver circuit chip package 120.

Outside the outermost first-second pattern 200p among the plurality of first-second patterns 200p of the first pad 200 of the display panel 100, the odd-numbered second-second pattern 300p of the second pad 300 of the driver circuit chip package 120 may be positioned. To achieve this, the number of second-second patterns 300p of the second pad 300 may be at least one more than the number of first-second patterns 200p of the first pad 200.

Referring to FIGS. 6 and 7, the second-second patterns 300p of the second pad 300 may be inserted into the spacing gaps between the first-second patterns 200p of the first pad 200. An insulating material layer 500 may be disposed between the first substrate 400 of the display panel 100 and the second substrate 121 of the driver circuit chip package 120. The second-second patterns 300p of the second pad 300 may penetrate the insulating material layer 500 to directly contact and couple with the first-second patterns 200p of the first pad 200. The insulating material layer 500 may include a resin.

The first-second patterns 200p of the first pads 200 may have a first surface 200a and a second surface 200b with different widths. The first surface 200a may be the surface in contact with the first substrate 400, and the second surface 200b may be the surface opposite the first surface 200a, facing the second substrate 121. For example, the first-second patterns 200p of the first pads 200 may have a tapered shape with a width that narrows from the first surface 200a to the second surface 200b. Accordingly, the first-second patterns 200p of the first pads 200 may have a trapezoidal shape when viewed in cross-section. In this case, the first-second patterns 200p of the first pads 200 may include an inclined surface 200i with a slope from the first surface 200a to the second surface 200b.

In contrast, the second-second patterns 300p of the second pads 300 may have a first surface 300a and a second surface 300b with the same width. Here, the first surface 300a of the second-second patterns 300p of the second pads 300 may be the surface in contact with the second substrate 121, and the second surface 300b may be the surface facing the first substrate 400. Accordingly, the second-second patterns 300p of the second pads 300 may have a rectangular shape when viewed in cross-section.

For example, the angle of each corner of the second-second patterns 300p of the second pads 300 may not be greater than 90 degrees. Therefore, the tip portion 300v of each corner of the second-second patterns 300p of the second pads 300 may be sharp enough to penetrate the insulating material layer 500 on the inclined surface 200i of the first pads 200. As shown in the enlarged portion of a region in FIG. 7, the tip portion (or sharp end) 300v of each corner of the second pads 300 may directly contact the inclined surface 200i of the first pads 200 of the display panel 100 in region ‘A’. Thus, the first pads 200 of the display panel 100 and the second pads 300 of the driver circuit chip package 120 may conduct through direct contact.

Referring to FIG. 8, at least the second-second patterns 300p among the second pads 300 of the driver circuit chip package 120 may extend along the length direction of the first-second patterns 200p among the first pads 200 of the display panel 100. Accordingly, each corner portion 300v of the second-second patterns 300p may make surface contact along the inclined surface 200i of the first-second patterns 200p in the length direction.

According to an embodiment of this specification, instead of using a point-contact method with conductive balls, electrical connection between the driver circuit chip and the display panel may be achieved through surface contact between the first-second patterns 200p and the second-second patterns 300p. This may increase the contact area between the first-second patterns 200p and the second-second patterns 300p compared to the point-contact method. Thus, contact resistance between the first-second patterns 200p and the second-second patterns 300p may be reduced, improving electrical conductivity.

The second-second patterns 300p among the second pads 300 of the driver circuit chip package 120 may be inserted into the spacing gaps between the first-second patterns 200p among the first pads 200 of the display panel 100 to contact the inclined surface 200i of each of the first pads 200. To achieve this, the width of each of the second-second patterns 300p of the driver circuit chip package 120 may be smaller than the width of the spacing gaps between the first-second patterns 200p of the display panel 100.

FIG. 9 is a cross-sectional view enlarging a portion where one first pad and one second pad are coupled.

Referring to FIGS. 6 and 9, when the first width a of the spacing gaps between adjacent first-second patterns 200p of the display panel 100 is a first size, the second width b between the inclined surfaces 200i of the adjacent first-second patterns 200p may be a second size larger than the first size. The second width b between the inclined surfaces 200i of the adjacent first-second patterns 200p may be the width between the end portions of the second surface 200b.

The second-second patterns 300p of the driver circuit chip package 120 may be inserted into the spacing gaps between the first-second patterns 200p of the display panel 100 to directly contact the inclined surface 200i of the first-second patterns 200p, and accordingly, the third width c of one second-second pattern 300p among the second-second patterns 300p may be larger than the first width a and smaller than the second width b.

Additionally, the fourth width d of the first surface 200a of the first-second patterns 200p of the display panel 100 may be equal to the difference between the second width b and the first width a. In one example, when the inclined surface 200i of the first-second patterns 200p of the display panel 100 has a 50-degree inclination angle relative to the first surface 200a, the first width a may be configured to be greater than 2 micrometers (µm). 2 micrometers (µm) may be the minimum value for forming the first-second patterns 200p of the display panel 100 through a photolithography process. In this case, the second width b may be configured to be greater than 4.5 micrometers (µm), which is larger than the first width a. Additionally, the width c of one second-second pattern 300p among the second-second patterns 300p of the driver circuit chip package 120 may be 3.5 micrometers (µm). The fourth width d of the first surface 200a of the first-second patterns 200p of the display panel 100 may be 2.5 micrometers (µm), equal to the difference between the second width b and the first width a. However, these values may vary depending on the inclination angle of the inclined surface 200i of the first-second patterns 200p of the display panel 100 relative to the first surface 200a, and thus are not limited to the aforementioned values.

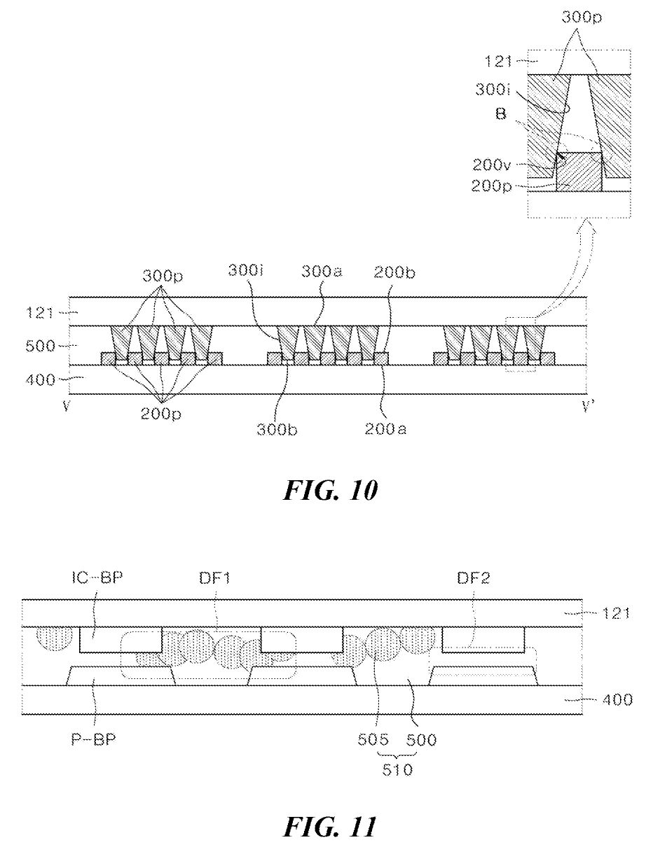

FIG. 10 is a diagram illustrating a cross-section along line V-V′ of FIG. 6 according to another embodiment of this specification.

Referring to FIG. 10, the second-second patterns 300p of the driver circuit chip package 120 may be inserted into the spaces gaps between the first-second patterns 200p of the display panel 100 to contact and couple with the first pads 200 of the display panel 100. An insulating material layer 500 may be disposed between the first substrate 400 of the display panel 100 and the second substrate 121 of the driver circuit chip package 120.

In this case, the second-second patterns 300p of the driver circuit chip package 120 may have a first surface 300a and a second surface 300b with different widths. The first surface 300a of the second-second patterns 300p may be the surface in contact with the second substrate 121, and the second surface 300b may be the surface opposite the first surface, arranged to face the first substrate 400. For example, the second-second patterns 300p of the second pads 300 may have a tapered shape with a width that narrows from the first surface 300a to the second surface 300b. In this case, the second-second patterns 300p may include an inclined surface 300i with a slope from the first surface 300a toward the second surface 300b.

The first-second patterns 200p of the display panel 100 may have a first surface 200a and a second surface 200b with the same width. The first surface 200a of the first-second patterns 200p may be the surface in contact with the first substrate 400 of the display panel 100, and the second surface 200b may be the surface opposite the first surface 200b. Accordingly, the first-second patterns 200p may have a rectangular shape when viewed in cross-section.

For example, the angle of each corner of the first-second patterns 200p may not be greater than 90 degrees. Thus, the tip portion 200v of each corner of the first-second patterns 200p may be sharp enough to penetrate the insulating material layer 500 on the inclined surface 200i of the first-second patterns 200p. As shown in the enlarged portion of a region in FIG. 10, the sharp end portion 200v of each corner of the first-second patterns 200p may directly contact the inclined surface 300i of each of the second-second patterns 300p in region ‘B’. Therefore, the first pads 200 of the display panel 100 and the second pads 300 of the driver circuit chip package 120 may conduct through direct contact between the patterns.

The first-second patterns 200p of the display panel 100 may be inserted into the spacing gaps between the second-second patterns 300p of the driver circuit chip package 120 to contact the inclined surface 300i of each of the second-second patterns 300p. Accordingly, the width of each of the first-second patterns 200p of the display panel 100 may be smaller than the width of the spacing gaps between the second-second patterns 300p of the driver circuit chip package 120.

Both inclined surfaces 300i of each of the second-second patterns 300p of the driver circuit chip package 120 may contact both corners 200v of the first-second patterns 200p of the display panel 100. To achieve this, when n (n is a natural number) second-second patterns 300p of the driver circuit chip package 120 are arranged, the first-second patterns 200p of the display panel 100 may be arranged in at least n+1 (n is a natural number).

According to an embodiment of this specification, the second-second patterns 300p among the second pads 300 of the driver circuit chip package 120 and the first-second patterns 200p among the first pads 200 of the display panel 100 may be electrically connected through direct contact. This allows for more stable signal transmission compared to a coupling method using conductive balls. This will be described below with reference to FIG. 11.

FIG. 11 is a diagram illustrating a display apparatus coupled using conductive balls.

Referring to FIG. 11, an anisotropic conductive film 510 with a plurality of conductive balls 505 dispersed in an insulating material layer 500 is disposed between the second substrate 121 of the driver circuit chip package and the first substrate 400 of the display panel 100. The second substrate 121 of the driver circuit chip has a first bump IC-BP as a connection terminal, and the first substrate 400 of the display panel 100 has a second bump P-BP as a connection terminal. The surfaces of the first bump IC-BP and the second bump P-BP may be disposed to face each other.

When pressure is applied between the first substrate 400 and the second substrate 121 with the anisotropic conductive film 510 in place, the plurality of conductive balls 505 may contact the first bump IC-BP and the second bump P-BP in the vertical direction. Thus, the first bump IC-BP and the second bump P-BP are electrically connected through contact with the conductive balls 505. As multiple conductive balls 505 are disposed between the first bump IC-BP and the second bump P-BP, this may be a point-contact method.

In this case, since the plurality of conductive balls 505 are disposed between the first bump IC-BP and the second bump P-BP, the conductive balls 505 dispersed in the horizontal direction must remain insulated from each other. However, as the first bumps IC-BP or the second bumps P-BP are formed with a fine pitch, defects DF1 and DF2 due to the conductive balls 505 may occur.

For example, defects may occur if the conductive balls 505 are not uniformly distributed. In one example, as conductive balls 505 are disposed between the first bumps IC-BP or second bumps P-BP spaced apart in the horizontal direction, a short-circuit defect DF1 may occur due to conduction in the horizontal direction. Alternatively, when conductive balls are not disposed between the first bump IC-BP and the second bump P-BP, an open defect DF2 may occur where the first bump IC-BP and the second bump P-BP are not electrically connected.

The coupling method using the anisotropic conductive film 510 relies on the conductive balls 505 for electrical connection, making it challenging to stably maintain the electrical connection between the display panel 100 and the driver circuit chip package 120 due to such variables. Additionally, since the coupling is achieved through point contact via the conductive balls 505, contact resistance may increase, leading to higher power consumption.

In contrast, the display apparatus according to an embodiment of this specification may electrically connect the second-second patterns 300p of the driver circuit chip package 120 and the first-second patterns 200p of the display panel 100 through direct surface contact. This allows stable electrical connection without using conductive balls. Moreover, omitting conductive balls may prevent short-circuit and open defects caused by them. Additionally, as the first-second patterns 200p and the second-second patterns 300p make direct surface contact, the contact area between the patterns 200p, 300p may increase. With an increased contact area, contact resistance between the patterns 200p and 300p may be reduced, improving electrical conductivity. Furthermore, since the first-second patterns 200p and the second-second patterns 300p are in direct contact, the signal path is shortened, preventing noise generation.

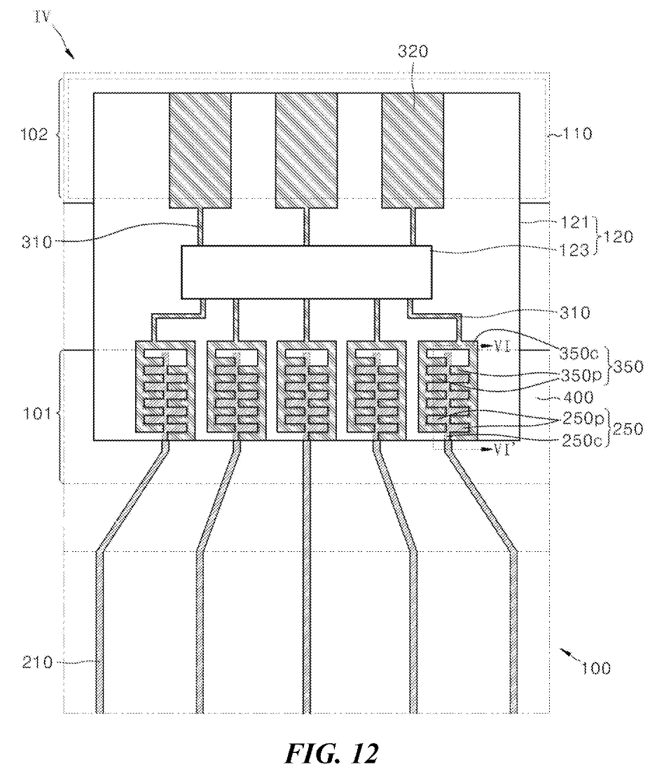

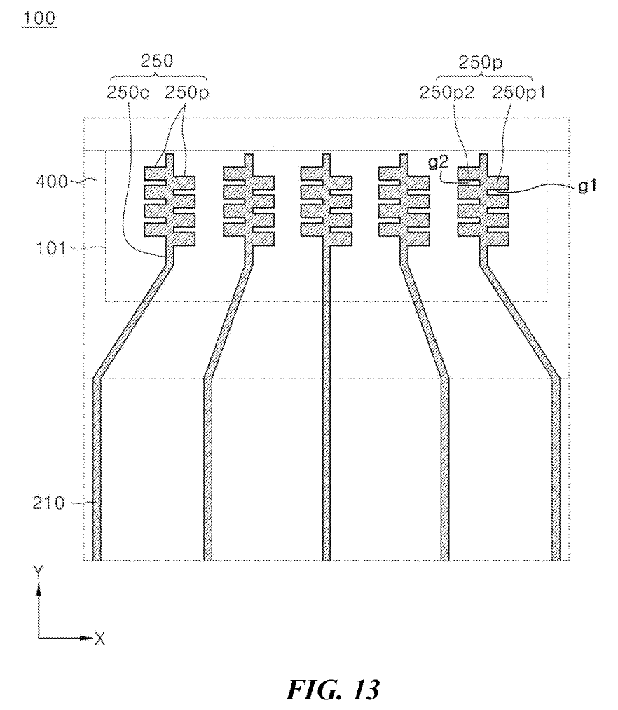

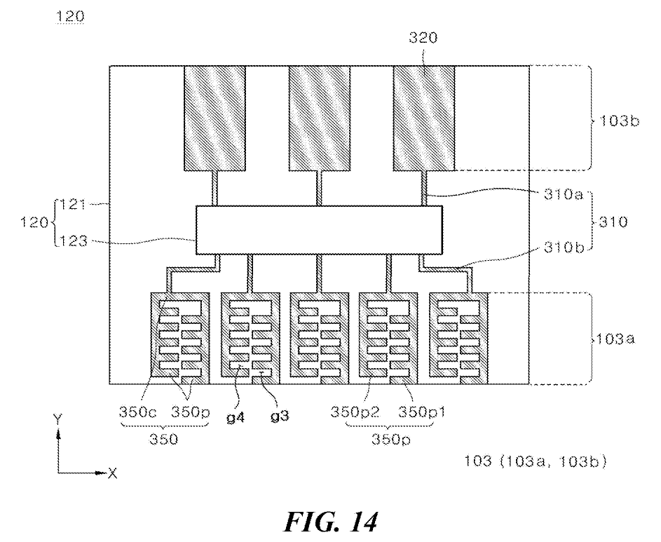

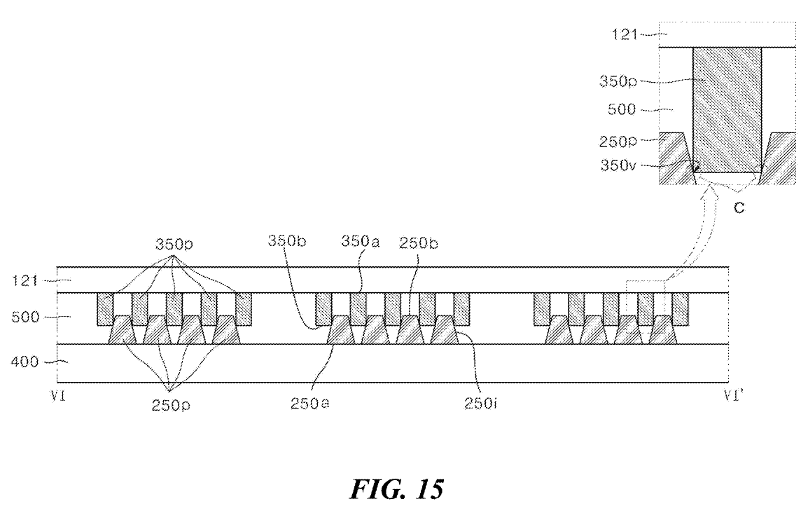

FIGS. 12 to 15 are diagrams illustrating a display apparatus according to another embodiment of this specification. Referring to FIG. 12, this is an enlarged plan view of area IV of FIG. 1 according to another embodiment of this specification. FIG. 13 is a diagram illustrating a portion of the first pad area of the display panel of FIG. 12. FIG. 14 is a diagram illustrating the driver circuit chip package of FIG. 12. And FIG. 15 is a cross-sectional view taken along line VI-VI′ of FIG. 12. Referring to FIGS. 12 to 15, the same reference numerals as those in FIGS. 3 to 7 may represent substantially the same components. Accordingly, redundant descriptions will be omitted or provided briefly.

Referring to FIGS. 12 to 15, first pads 250 and a plurality of first wirings 210 may be disposed on the first substrate 400 of the display panel 100. The first pads 250 may be input pads.

Referring to FIGS. 12 and 13, the first pads 250 may be disposed in the first pad area 101. The first pads 250 may be arranged spaced apart from each other along the first direction X of the first substrate 400. The first pads 250 may couple with the second pads 350, which are output pads of the driver circuit chip package, to be electrically connected.

One first pad 250 may include a first-first pattern 250c and a plurality of first-second patterns 250p branching and diverging from the first-first pattern 250c. For example, the first-first pattern 250c may extend along the second direction Y of the first substrate 400. The first-first pattern 250c may be connected to a first wiring 210 extending from the display area DA (refer to FIG. 1). The first wiring 210 may be a data line transmitting data signals to a plurality of pixels in the display area, but is not limited thereto.

Each of the plurality of first-second patterns 250p may branch and diverge from the first-first pattern 250c and be arranged along the first direction X, different from the second direction Y. The plurality of first-second patterns 250p may include a plurality of first-first protrusions 250p1 and a plurality of first-second protrusions 250p2. The plurality of first-first protrusions 250p1 and the plurality of first-second protrusions 250p2 may be disposed in different directions. For example, the first-first protrusions 250p1 among the plurality of first-second patterns 250p may protrude in one side direction, and the first-second protrusions 250p2 may protrude in the other side direction from the first-first pattern 250c.

The adjacent first-first protrusions 250p1 may be spaced apart from each other by a first gap g1. The adjacent first-second protrusions 250p2 may be spaced apart from each other by a second gap g2. For example, the first-first protrusions 250p1 may be disposed at positions corresponding to the second gap g2 of the first-second protrusions 250p2 on one side of the first-first pattern 250c, and the first-second protrusions 250p2 may be disposed at positions corresponding to the first gap g1 of the first-first protrusions 250p1 on the other side of the first-first pattern 250c. Accordingly, the plurality of first-first protrusions 250p1 and the plurality of first-second protrusions 250p2 may be alternately arranged with the first-first pattern 250c in between.

Accordingly, the plurality of first-first protrusions 250p1 and the plurality of first-second protrusions 250p2 may be alternately arranged with the first-first pattern 250c in between. The first signal supplied to the plurality of first-second patterns 250p may be merged into a single first signal at the first-first pattern 250c and transmitted to the sub-pixels on the display panel 100. In this case, the first signal branched from the plurality of first-second patterns 250p and the first signal at the first-first pattern 250c may be the same signal.

The signal supplied to the plurality of first-second patterns 250p may be provided from the printed circuit board 110 and transmitted to the display panel 100 through the pads 320, 350 of the driver circuit chip package 120 shown in FIG. 14.

The signal supplied to the plurality of first-second patterns 250p may be provided from the printed circuit board 110 and transmitted to the display panel 100 through the pads 320, 350 of the driver circuit chip package 120 shown in FIG. 14. The second pads 320, 350 may include second pads 350 and third pads 320. The second pads 350 may be referred to as output pads, and the third pads 320 may be referred to as input pads. The plurality of second wirings 310 may include a first portion 310a and a second portion 310b.

The second pads 350 may be disposed in the first region 103a of the second pad area 103, and the third pads 320 may be disposed in the second region 103b. The second pads 350 may be connected to the first pads 250 of the display panel 100.

One second pad 350 may include a second-first pattern 350c and a plurality of second-second patterns 350p branching and diverging from the second-first pattern 350c. For example, the second-first pattern 350c may have a shape extending along the first direction X of the second substrate 121. One second-first pattern 350c may be connected to the second portion 310b among the plurality of second wirings 310.

The plurality of second-second patterns 350p may branch and diverge from the second-first pattern 350c. One second-second pattern 350p may include a plurality of second-first protrusions 350p1 and a plurality of second-second protrusions 350p2. Each of the plurality of second-first protrusions 350p1 and the plurality of second-second protrusions 350p2 may have a comb-like protruding shape. The plurality of second-first protrusions 350p1 and the plurality of second-second protrusions 350p2 may be disposed in different directions. For example, each second-first protrusion 350p1 may protrude in one side direction (or left direction), and each second-second protrusion 350p2 may protrude in the other side direction (or right direction). In one example, the end portion of the second-second protrusions 350p2 may be arranged to protrude in a direction facing the end portion of the second-first protrusions 350p1 alternately. In one example, the end portion of the second-second protrusions 350p2 and the end portion of the second-first protrusions 350p1 may protrude in a zigzag pattern alternately.

The adjacent second-first protrusions 350p1 may be arranged spaced apart from each other by a third gap g3 in the second direction Y of the second substrate 121. The adjacent second-second protrusions 350p2 may be arranged spaced apart from each other by a fourth gap g4 in the second direction Y of the second substrate 121. For example, the second-first protrusions 350p1 may be disposed at positions corresponding to the fourth gap g4 of the second-second protrusions 350p2, and the second-second protrusions 350p2 may be disposed at positions corresponding to the third gap g3 of the second-first protrusions 350p1 on the other side. Accordingly, the plurality of second-first protrusions 350p1 and the plurality of second-second protrusions 350p2 may be alternately arranged.

Referring to FIGS. 12 and 15, the first pads 250 of the display panel 100 and the third pads 350 of the driver circuit chip package 120 may be coupled by overlapping in the vertical direction.

For example, the plurality of second-second protrusions 350p2 among the second-second patterns 350p of the driver circuit chip package 120 may be coupled in the space of the second gap g2 between the first-second protrusions 250p2 among the first-second patterns 250p of the display panel 100. Additionally, the plurality of second-first protrusions 350p1 among the second-second patterns 350p of the driver circuit chip package 120 may be coupled in the space of the first gap g1 between the first-first protrusions 250p1 among the first-second patterns 250p of the display panel 100.

The plurality of first-second patterns 250p, including the first-first protrusions 250p1 and the first-second protrusions 250p2 of the display panel 100, may have a first surface 250a and a second surface 250b with different widths. The first-second patterns 250p may have a tapered shape including an inclined surface 250i with a slope from the first surface 250a to the second surface 250b.

The second-second patterns 350p, including the second-first protrusions 350p1 and the second-second protrusions 350p2 of the driver circuit chip package 120, may have a first surface 350a and a second surface 350b with the same width. Accordingly, the second-second patterns 350p may have a rectangular shape when viewed in cross-section.

The tip portion 350v of each corner of the second-second patterns 350p may be sharp enough to penetrate the insulating material layer 500 on the inclined surface 250i of the first pads 250. As a result, the tip portion (or sharp end) 350v of each corner of the second pads 350 may directly contact the inclined surface 250i of the first-second patterns 250p of the display panel 100 in region ‘C’. Thus, the first-second patterns 250p of the display panel 100 and the second-second patterns 350p of the driver circuit chip package 120 may conduct through direct contact between their respective protrusions.

A signal supplied from the printed circuit board 110 may be converted by the driver circuit chip 123, and the converted signal may be provided to the display panel 100 through the second pads 350. Here, a signal supplied to one second pad 350 may branch from the second-first pattern 350c to the second-first protrusions 350p1 and the second-second protrusions 350p2.

The branched signal may be transmitted to the first-first pattern 250c through the first-first protrusions 250p1 and the first-second protrusions 250p2, respectively coupled with the second-first protrusions 350p1 and the second-second protrusions 350p2. And the signal may be transmitted to a plurality of pixels in the display area through the first wiring 210 connected to the first-first pattern 250c.

Here, the signal supplied to one second pad 350, the signal supplied to the second-first pattern 350c, the signals branched to the second-first protrusions 350p1 and the second-second protrusions 350p2 of the second-second pattern 350p, and the signal transmitted to the display area through the first wiring 210 may be the same signal.

Accordingly, even if a defect occurs in one of the plurality of second-second patterns 350p of the second pad 350, the same signal provided by the driver circuit chip 123 may be transmitted to the display area through the remaining second-second patterns 350p. This ensures the signal provided by the driver circuit chip 123 is transmitted to the display area without loss, thereby improving the reliability of the display apparatus.

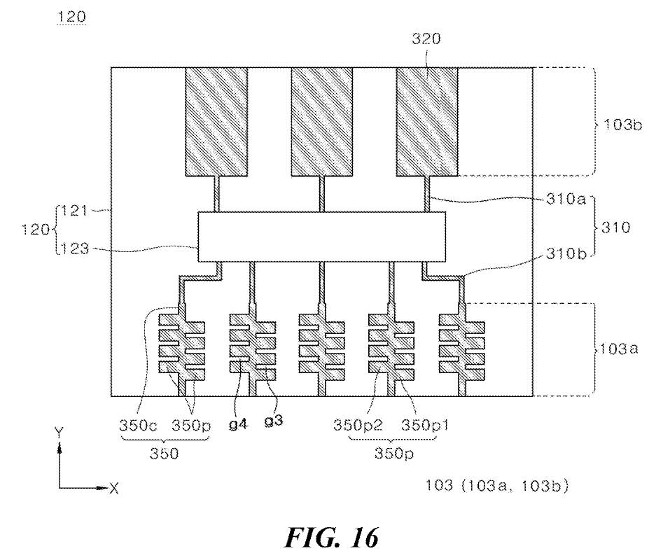

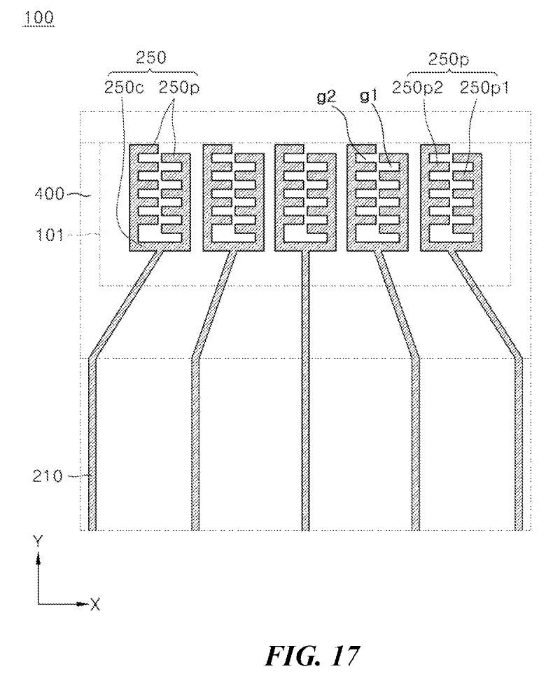

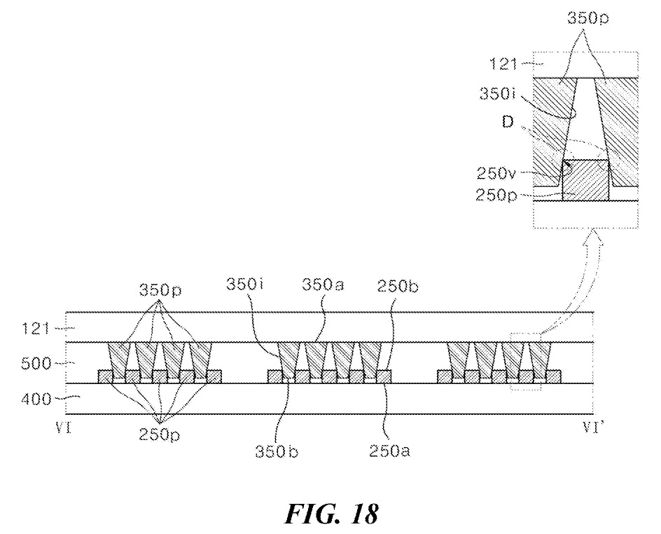

FIGS. 16 to 18 are diagrams illustrating a display apparatus according to yet another embodiment of this specification. FIG. 16 illustrates a driving circuit chip package. FIG. 17 is a diagram illustrating a portion of the pad area of the display panel. FIG. 18 is a cross-sectional view illustrating the driver circuit chip package of FIG. 16 coupled with the pad area of the display panel of FIG. 17. FIGS. 16 and 17 differ from FIGS. 13 to 15 in the shapes of the first pads 250 and the second pads 350. Accordingly, redundant descriptions of components with the same reference numerals will be omitted or provided briefly.

Referring to FIGS. 16 to 18, second pads 350, third pads 320, and a plurality of second wirings 310 may be disposed on the second substrate 121 of the driver circuit chip package 120. Referring to FIG. 16, each of the second pads 350 may include a second-first pattern 350c and a plurality of second-second patterns 350p. The second-first pattern 350c may extend along the second direction Y of the second substrate 121. The second-first pattern 350c may extend along the second direction Y of the second substrate 121.

The plurality of second-second patterns 350p may branch and diverge from the second-first pattern 350c. For example, the plurality of second-second patterns 350p may include a plurality of second-first protrusions 350p1 and a plurality of second-second protrusions 350p2, branching and disposed on both sides with the second-first pattern 350c in between. The plurality of second-first protrusions 350p1 and the plurality of second-second protrusions 350p2 may be disposed in different directions. For example, each second-first protrusion 350p1 may protrude in one side direction of the second-first pattern 350c, and each second-second protrusion 350p2 may protrude in the other side direction of the second-first pattern 350c.

The adjacent second-first protrusions 350p1 may be spaced apart from each other by a third gap g3, and the adjacent second-second protrusions 350p2 may be spaced apart from each other by a fourth gap g4. In this case, the second-first protrusions 350p1 may be disposed at positions corresponding to the fourth gap g4 of the second-second protrusions 350p2, and the second-second protrusions 350p2 may be disposed at positions corresponding to the third gap g3 of the second-first protrusions 350p1. Accordingly, the plurality of second-first protrusions 350p1 and the plurality of second-second protrusions 350p2 may be alternately arranged.

Referring to FIGS. 17 and 18, first pads 250 and a plurality of first wirings 210 may be disposed on the first substrate 400 of the display panel 100. The first pads 250 may be disposed in the first pad area 101. The first pads 250 may couple with the second pads 350 of the driver circuit chip package 120 to be electrically connected.

One first pad 250 may include a first-first pattern 250c and a plurality of first-second patterns 250p. One first-first pattern 250c may be connected to one of the first wirings 210. The first wirings 210 may extend to the display area.

Each of the plurality of first-second patterns 250p may branch and diverge from the first-first pattern 250c. One first-second pattern 250p may include a plurality of first-first protrusions 250p1 and a plurality of first-second protrusions 250p2. Each of the first-first protrusions 250p1 and the first-second protrusions 250p2 may have a comb-like protruding shape. The plurality of first-first protrusions 250p1 and the plurality of first-second protrusions 250p2 may be disposed in directions facing each other.

The adjacent first-first protrusions 250p1 may be spaced apart from each other by a first gap g1 in the second direction Y of the first substrate 400. The adjacent first-second protrusions 250p2 may be spaced apart from each other by a second gap g2 in the second direction Y of the first substrate 400. For example, the first-first protrusions 250p1 may be disposed at positions corresponding to the second gap g2 of the first-second protrusions 250p2, and the first-second protrusions 250p2 may be disposed at positions corresponding to the first gap g1 of the first-first protrusions 250p1. Accordingly, the plurality of first-first protrusions 250p1 and the plurality of first-second protrusions 250p2 may be alternately arranged.

Referring again to FIG. 18, the first pads 250 of the display panel 100 and the third pads 350 of the driver circuit chip package 120 may be coupled to directly contact each other in the vertical direction.

For example, the second-second patterns 350p on the second substrate 121 may be inserted into the first gap g1 and the second gap g2, which are the spacing between the first-second patterns 250p on the first substrate 400. The first surface 350a and the second surface 350b of the second-second patterns 350p may have different widths. Accordingly, an inclined surface 350i with a slope may be disposed between the first surface 350a and the second surface 350b of the second-second patterns 350p.

Additionally, the first-second patterns 250p on the first substrate 400 may have a first surface 250a and a second surface 250b with the same width. Accordingly, the first-second patterns 250p may have a rectangular shape with right-angled corners when viewed in cross-section. Thus, the tip portion 250v of each corner of the first-second patterns 250p may be sharp enough to penetrate the insulating material layer 500 on the inclined surface 350i of the second-second patterns 350p.

As shown in the enlarged portion of a region in FIG. 18, the first-second patterns 250p may penetrate the insulating material layer 500 due to the sharp shape of the tip portion 250v of each corner, directly contacting the inclined surface 350i of the second-second patterns 350p at portion ‘D’. Accordingly, the first-second patterns 250p of the display panel 100 and the second-second patterns 350p of the driver circuit chip package 120 may conduct through direct contact between their respective protrusions.

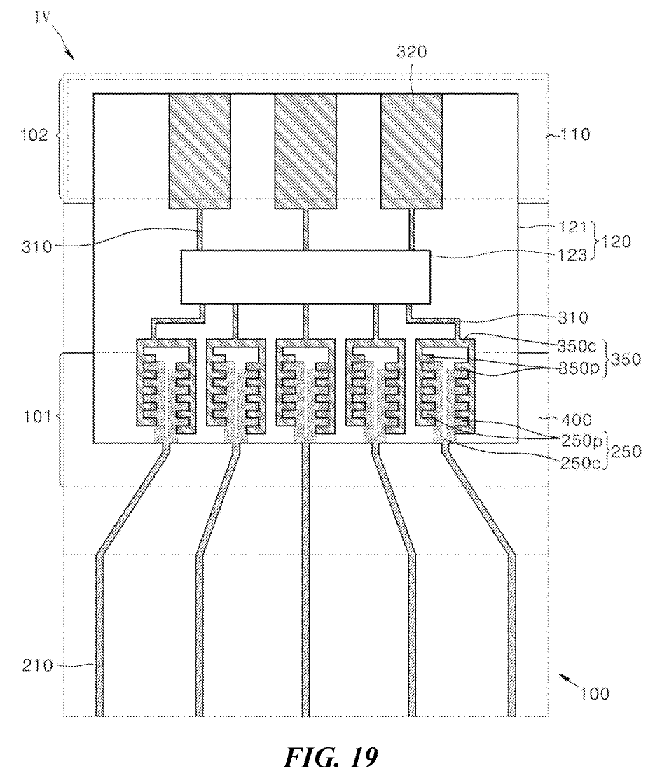

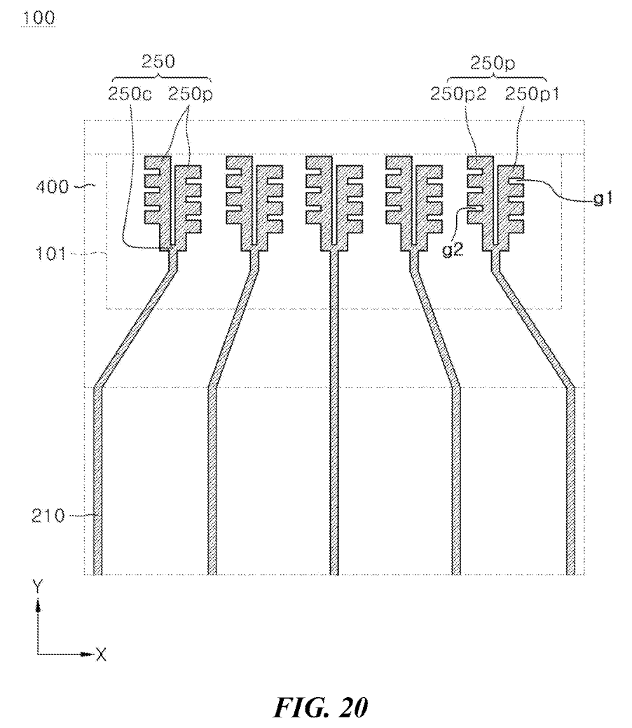

FIGS. 19 and 20 are diagrams illustrating a display apparatus according to still another embodiment of this specification. Referring to FIG. 19, this is an enlarged plan view of area IV of FIG. 1 according to another embodiment of this specification. FIG. 20 is a diagram illustrating a portion of the pad area of the display panel. In FIGS. 19 and 20, the third pads 350 on the driver circuit chip package 120 may be configured to have substantially the same shape as the third pads 350 in FIG. 14. Accordingly, redundant descriptions will be omitted or provided briefly.

Referring to FIGS. 19 and 20, first pads 250 and a plurality of first wirings 210 may be disposed on the first substrate 400 of the display panel 100. The first pads 250 may couple with the second pads 350 of the driver circuit chip package 120 through direct contact to be electrically connected.

One first pad 250 may include a first-first pattern 250c and a plurality of first-second patterns 250p. One first-first pattern 250c may be connected to one of the first wirings 210. One first-first pattern 250c may have a rod shape extending in the first direction X of the first substrate 400, but is not limited thereto. The first wirings 210 may extend to the display area to transmit signals to sub-pixels.

Each of the plurality of first-second patterns 250p may branch and diverge from the first-first pattern 250c. One first-second pattern 250p may include a plurality of first-first protrusions 250p1 and a plurality of first-second protrusions 250p2. Each of the first-first protrusions 250p1 and the first-second protrusions 250p2 may have a comb-like protruding shape.

The plurality of first-first protrusions 250p1 and the plurality of first-second protrusions 250p2 may be disposed in different directions. For example, each second-first protrusion 350p1 (see FIG. 14) may have protrusions protruding in one side direction of the second-first pattern 350c, and each second-second protrusion 350p2 (see FIG. 14) may have protrusions protruding in the other side direction of the second-first pattern 350c. In one example, the end portion of the protrusion of the first-second protrusion 250p2 may be disposed in a direction opposite to the end portion of the protrusion of the first-first protrusion 250p1.

The protrusions of the adjacent first-first protrusions 250p1 may be spaced apart from each other by a first gap g1. The protrusions of the adjacent first-second protrusions 250p2 may be spaced apart from each other by a second gap g2. For example, the first-first protrusions 250p1 may be disposed at positions corresponding to the second gap g2 on one side of the first pattern 250c, and the first-second protrusions 250p2 may be disposed at positions corresponding to the first gap g1 on the other side of the first-first pattern 250c. Accordingly, the plurality of first-first protrusions 250p1 and the plurality of first-second protrusions 250p2 may be alternately arranged.

Referring to FIG. 19, the second pads 350 of the driver circuit chip package 120 may be inserted at positions corresponding to the first gap g1 and the second gap g2, which are the spaces between the first pads 250 of the display panel 100, with an insulating material layer 500 in between, and conduct through direct contact with the first pads 250 of the display panel 100. For example, the second-first protrusions 350p1 among the second-second patterns 350p of the second pads 350 may be inserted into the first gap g1 between the first-first protrusions 250p1 of the first-second patterns 250p of the first pads 250. Accordingly, the second-first protrusions 350p1 may directly contact the first-first protrusions 250p1. Additionally, the second-second protrusions 350p2 among the second-second patterns 350p may be inserted into the second gap g2 between the first-second protrusions 250p2 of the first-second patterns 250p of the first pads 250. Accordingly, the second-second protrusions 350p2 may directly contact the first-second protrusions 250p2.

According to embodiments of this specification, the driver circuit chip package and the display panel may be electrically connected by coupling their respective pads through surface contact. This allows the omission of conductive balls, preventing short-circuit and open defects. As a result, electrical connection between the display panel and the driver circuit chip can be stably achieved, reducing the defect rate of the display apparatus. Consequently, production energy required for manufacturing the display apparatus can be reduced, and greenhouse gas emissions can be lowered.

Additionally, as the pads are coupled through direct surface contact, the contact area may increase. This can reduce contact resistance, improving electrical conductivity.

Moreover, omitting conductive balls eliminates the design margin needed for their placement, allowing pads to be arranged with a higher level of fine pitch. Accordingly, the area of the pad region can be reduced within the same area. Therefore, pads can be arranged more densely per unit area. This facilitates the implementation of high-resolution display apparatuses.

Furthermore, since the driver circuit chip and the display panel can be electrically connected without conductive balls, the cost associated with the process step of arranging conductive balls can be reduced.

The display apparatus according to various embodiments of this specification may be described as follows.

A display apparatus according to an embodiment of this specification may include a first substrate on which a plurality of first pads each including first patterns arranged with spacing gaps in between are disposed, and a second substrate disposed on the first substrate, with a plurality of second pads each including a second pattern coupled with the first patterns, wherein the second patterns may be inserted into the respective spacing gaps to contact the side surfaces of the first patterns.

According to various embodiments of this specification, the first substrate may include a plurality of sub-pixels, and the second substrate comprises a driver circuit chip.

According to various embodiments of this specification, the first patterns of one first pad among the plurality of first pads may include a first-first pattern extending in a first direction of the first substrate and a plurality of first-second patterns extending in a second direction different from the first-first pattern, and the second patterns of one second pad among the plurality of second pads may include a second-first pattern extending in a first direction of the second substrate and a plurality of second-second patterns extending in a second direction different from the first-first pattern.

According to various embodiments of this specification, the first-first pattern and the plurality of first-second patterns may be integrally formed, and the second-first pattern and the plurality of second-second patterns may be integrally formed.

According to various embodiments of this specification, each of the plurality of first-second patterns may be arranged spaced apart from each other in the first direction of the first substrate with a first space therebetween, and each of the plurality of second-second patterns may be arranged spaced apart from each other in the first direction of the second substrate with a second space therebetween.

According to various embodiments of this specification, each of the plurality of first-second patterns may include a first surface with a first width and a second surface with a second width different from the first width, the first surface to the second surface including an inclined surface with a slope, and each of the plurality of second-second patterns may include a first surface with a first width and a second surface with a second width equal to the first width.

According to various embodiments of this specification, the first surface of the plurality of first-second patterns may contact the first substrate and the first surface of the plurality of second-second patterns may contacts the second substrate, and the second surface of the plurality of first-second patterns may face the second substrate and the second surface of the plurality of second-second patterns may face the first substrate.

According to various embodiments of this specification, each of the plurality of second-second patterns may be inserted into the first space to contact the inclined surface of the plurality of first-second patterns.

According to various embodiments of this specification, each of the plurality of second-second patterns may have a corner portion contacting the inclined surface of each of the first-second patterns.

The display apparatus according to various embodiments of this specification may further include an insulating material layer disposed between the first substrate and the second substrate, wherein each of the plurality of second-second patterns may penetrate the insulating material layer.

According to various embodiments of this specification, the first width of the first space between adjacent first-second patterns may be a first size, the second width between the end portions of the second surfaces of the adjacent first-second patterns may be a second size larger than the first size, and the third width of one second-second pattern may be smaller than the second size of the second width.

According to various embodiments of this specification, each of the plurality of first-second patterns may include a first surface with a first width and a second surface with a second width equal to the first width, and each of the plurality of second-second patterns may include a first surface with a first width and a second surface with a second width different from the first width, the first surface to the second surface including an inclined surface with a slope.

According to various embodiments of this specification, the first surface of the plurality of first-second patterns may contact the first substrate and the first surface of the plurality of second-second patterns may contacts the second substrate, and the second surface of the plurality of first-second patterns may face the second substrate and the second surface of the plurality of second-second patterns may face the first substrate.

According to various embodiments of this specification, each of the plurality of second-second patterns may be inserted into the first space, and each corner portion of the plurality of first-second patterns may contact the inclined surface of the plurality of second-second patterns.

The display apparatus according to various embodiments of this specification may further include an insulating material layer disposed between the first substrate and the second substrate, wherein each of the plurality of first-second patterns may penetrate the insulating material layer.

According to various embodiments of this specification, each of the plurality of first-second patterns may include a plurality of first-first protrusions protruding in one side direction of the first-first pattern and a plurality of first-second protrusions protruding in the other side direction of the first-first pattern, and each of the plurality of second-second patterns may include a plurality of second-first protrusions and a plurality of second-second protrusions, the second-first protrusions and the second-second protrusions protruding in a comb-like shape.

According to various embodiments of this specification, the second-first protrusions and the second-second protrusions may have respective end portions protruding in directions facing each other.

According to various embodiments of this specification, each of the plurality of first-second patterns may include a plurality of first-first protrusions and a plurality of first-second protrusions, and each of the plurality of second-second patterns may include a plurality of second-first protrusions protruding in one side direction of the second-first pattern and a plurality of second-second protrusions protruding in the other side direction of the second-first pattern, wherein the first-first protrusions and the first-second protrusions of the first-second patterns may protrude in a comb-like shape.

According to various embodiments of this specification, each of the plurality of first-second patterns may include a plurality of first-first protrusions and a plurality of first-second protrusions protruding in the other side direction of the first-first pattern, and each of the plurality of second-second patterns may include a plurality of second-first protrusions and a plurality of second-second protrusions, wherein the first-first protrusions, the first-second protrusions, the second-first protrusions, and the second-second protrusions may each protrude in a comb-like shape, the second-first protrusions and the second-second protrusions may have respective end portions protruding in alternating directions facing each other, and the first-first protrusions and the first-second protrusions may have respective end portions protruding in directions facing each other.

According to various embodiments of this specification, each of the plurality of first-second patterns may include a plurality of first-first protrusions and a plurality of first-second protrusions protruding in the other side direction of the first-first pattern, and each of the plurality of second-second patterns may include a plurality of second-first protrusions and a plurality of second-second protrusions, wherein the first-first protrusions, the first-second protrusions, the second-first protrusions, and the second-second protrusions may each protrude in a comb-like shape, the second-first protrusions and the second-second protrusions may have respective end portions protruding in a zigzag alternating pattern, and the first-first protrusions and the first-second protrusions may have respective end portions protruding in directions facing each other.

According to the embodiments of this specification, one input pad of a display panel and one output pad of a driver circuit chip package can each be configured with a structure in which a plurality of patterns are coupled together. This allows the omission of conductive balls, preventing short-circuit or open defects caused by conductive balls.

As a result, electrical connection between the display panel and the driver circuit chip can be stably achieved, reducing the defect rate of the display apparatus. Consequently, production energy required for manufacturing the display apparatus can be reduced, and greenhouse gas emissions can be lowered.

Furthermore, since the driver circuit chip and the display panel can be electrically connected without conductive balls, the design margin required for bonding pads when using conductive balls can be secured, allowing for the configuration of bonding pads with a finer pitch and facilitating the implementation of a high-resolution display apparatus.

The various embodiments of a display apparatus allows the first and second substrates to achieve electrical connection through direct surface contact without the need for conductive balls. As a result, the display apparatus can reduce connection defects, improve electrical reliability, support finer pitch arrangements, and enable more compact, high-resolution display designs while contributing to energy savings and reduced manufacturing complexity.

Additionally, electrically connecting the driver circuit chip and the display panel without conductive balls can reduce costs.

The advantageous effects of this specification are not limited to the foregoing, and other effects not mentioned will be clearly understood by those skilled in the art from the detailed description.

Although embodiments of this specification have been described in detail with reference to the accompanying drawings, it should be noted that the specification is not necessarily limited to these embodiments and can be modified in various ways without departing from the scope of the technical concept of the disclosure. Therefore, the embodiments disclosed in this specification are not intended to limit but to describe the technical idea of the specification, and the scope of the technical idea of the specification is not limited by the embodiments. Therefore, it should be understood that the embodiments described above are exemplary and not limited in all aspects.

The various embodiments described above can be combined to provide further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display apparatus comprising:
a first substrate on which a plurality of first pads each including first patterns arranged with spacing gaps in between are disposed; and
a second substrate on the first substrate, with a plurality of second pads each including a second pattern coupled with the first patterns,
wherein the second patterns are inserted into the respective spacing gaps to contact the side surfaces of the first patterns.

2. The display apparatus of claim 1, wherein the first substrate comprises a plurality of sub-pixels, and the second substrate comprises a driver circuit chip.

3. The display apparatus of claim 1, wherein the first patterns of one first pad among the plurality of first pads comprises a first-first pattern extending in a first direction of the first substrate and a plurality of first-second patterns extending in a second direction different from the first-first pattern, and the second patterns of one second pad among the plurality of second pads comprise a second-first pattern extending in a first direction of the second substrate and a plurality of second-second patterns extending in a second direction different from the first-first pattern.

4. The display apparatus of claim 3, wherein the first-first pattern and the plurality of first-second patterns are integrally formed, and the second-first pattern and the plurality of second-second patterns are integrally formed.

5. The display apparatus of claim 3, wherein each of the plurality of first-second patterns is arranged spaced apart from each other in the first direction of the first substrate with a first spacing gap therebetween,
and each of the plurality of second-second patterns is arranged spaced apart from each other in the first direction of the second substrate with a second spacing gap therebetween.

6. The display apparatus of claim 5, wherein each of the plurality of first-second patterns comprises a first surface with a first width and a second surface with a second width different from the first width, the first surface to the second surface including an inclined surface with a slope, and each of the plurality of second-second patterns comprises a first surface with a first width and a second surface with a second width equal to the first width.

7. The display apparatus of claim 6, wherein the first surface of the plurality of first-second patterns contacts the first substrate and the first surface of the plurality of second-second patterns contacts the second substrate, and the second surface of the plurality of first-second patterns faces the second substrate and the second surface of the plurality of second-second patterns faces the first substrate.

8. The display apparatus of claim 6, wherein each of the plurality of second-second patterns is inserted into the first space to contact the inclined surface of the plurality of first-second patterns.

9. The display apparatus of claim 6, wherein each of the plurality of second-second patterns has a corner portion contacting the inclined surface of each of the first-second patterns.

10. The display apparatus of claim 8, further comprising an insulating material layer disposed between the first substrate and the second substrate,
wherein each of the plurality of second-second patterns penetrates the insulating material layer.

11. The display apparatus of claim 6, wherein the first width of the first spacing gap between adjacent first-second patterns is a first size, the second width between the end portions of the second surfaces of the adjacent first-second patterns is a second size larger than the first size, and the third width of one second-second pattern is smaller than the second size of the second width.

12. The display apparatus of claim 3, wherein each of the plurality of first-second patterns comprises a first surface with a first width and a second surface with a second width equal to the first width, and each of the plurality of second-second patterns comprises a first surface with a first width and a second surface with a second width different from the first width, the first surface to the second surface including an inclined surface with a slope.

13. The display apparatus of claim 12, wherein the first surface of the plurality of first-second patterns contacts the first substrate and the first surface of the plurality of second-second patterns contacts the second substrate, and the second surface of the plurality of first-second patterns faces the second substrate and the second surface of the plurality of second-second patterns faces the first substrate.

14. The display apparatus of claim 12, wherein each of the plurality of second-second patterns is inserted into the first spacing gap, and each corner portion of the plurality of first-second patterns contacts the inclined surface of the plurality of second-second patterns.

15. The display apparatus of claim 3, wherein each of the plurality of first-second patterns comprises a plurality of first-first protrusions protruding in one side direction of the first-first pattern and a plurality of first-second protrusions protruding in the other side direction of the first-first pattern, and each of the plurality of second-second patterns comprises a plurality of second-first protrusions and a plurality of second-second protrusions, the second-first protrusions and the second-second protrusions protruding in a comb-like shape.

16. The display apparatus of claim 15, wherein the second-first protrusions and the second-second protrusions have respective end portions protruding in directions facing each other.

17. The display apparatus of claim 3, wherein each of the plurality of first-second patterns comprises a plurality of first-first protrusions and a plurality of first-second protrusions, and each of the plurality of second-second patterns comprises a plurality of second-first protrusions protruding in one side direction of the second-first pattern and a plurality of second-second protrusions protruding in the other side direction of the second-first pattern,
wherein the first-first protrusions and the first-second protrusions of the first-second patterns protrude in a comb-like shape.

18. The display apparatus of claim 3, wherein each of the plurality of first-second patterns comprises a plurality of first-first protrusions and a plurality of first-second protrusions protruding in the other side direction of the first-first pattern, and each of the plurality of second-second patterns comprises a plurality of second-first protrusions and a plurality of second-second protrusions,
wherein the first-first protrusions, the first-second protrusions, the second-first protrusions, and the second-second protrusions each protrude in a comb-like shape, the second-first protrusions and the second-second protrusions have respective end portions protruding in alternating directions facing each other, and the first-first protrusions and the first-second protrusions have respective end portions protruding in directions facing each other.

19. The display apparatus of claim 3, wherein each of the plurality of first-second patterns comprises a plurality of first-first protrusions and a plurality of first-second protrusions protruding in the other side direction of the first-first pattern, and each of the plurality of second-second patterns comprises a plurality of second-first protrusions and a plurality of second-second protrusions, wherein the first-first protrusions, the first-second protrusions, the second-first protrusions, and the second-second protrusions each protrude in a comb-like shape, the second-first protrusions and the second-second protrusions have respective end portions protruding in a zigzag alternating pattern, and the first-first protrusions and the first-second protrusions have respective end portions protruding in directions facing each other.

20. The display apparatus of claim 1, further comprising an insulating material layer,
wherein the first substrate and second substrate are directly and electrically coupled by contact between the first patterns and second patterns, with the insulating material layer disposed therebetween.
